(19) United States
(12) Patent Application Publication
(10) Pub. No.: US 2020/0035900 A1
(43) Pub. Date: Jan. 30, 2020

(54) THERMOELECTRIC DEVICE

(71) Applicant: Mahle International GmbH, Stuttgart (DE)

(72) Inventors: Juergen Gruenwald, Ludwigsburg (DE); Stefan Hoppe, Dorsten (DE); Andreas Kemle, Tamm (DE); Jan Schoener, Dorsten (DE)

(21) Appl. No.: 16/521,583

(22) Filed: Jul. 24, 2019

(30) Foreign Application Priority Data
Jul. 25, 2018 (DE) 102018212426.4

(51) Int. Cl. H01L 35/32; H01L 35/08; H01L 35/34

(52) U.S. Cl. CPC H01L 35/32; H01L 35/34; H01L 35/08

(57) ABSTRACT

A thermoelectric device may include a housing made of a plastic, which may partially limit an interior space and which may include a first side wall and a second side wall lying opposite to the first side wall, and a thermoelectric element made of a thermoelectrically active material arranged in the interior space. The first electrical connection element may be arranged on an inner side of the first side wall, and a second electrical connection element may be arranged on an inner side of the second side wall. The first electrical connection element may be connected in a substance-to-substance manner to a first front side of the thermoelectric element facing the first side wall, and the second electrical connection element may be connected to a second front side of the thermoelectric element facing the second side wall.

### CROSS-REFERENCE TO RELATED APPLICATION

This application claims priority to German Patent Application No. DE 10 2018 212 426.4, filed Jul. 25, 2018, which is hereby incorporated in its entirety.

### TECHNICAL FIELD

The invention relates to a thermoelectric device. The invention furthermore relates to a thermoelectric assembly with such a thermoelectric device.

### BACKGROUND

Thermoelectric elements of a thermoelectric device consist of thermoelectrically active semiconductor materials that convert a temperature difference into a potential difference, i.e. an electrical voltage, and vice versa. In this way, a heat flow can be converted into an electrical current and vice versa. The thermoelectric elements are based on the Peltier effect when converting electrical energy into heat, and on the Seebeck effect when converting heat into electrical energy. Within a thermoelectric module, p-doped and n-doped thermoelectric elements are interconnected among one another. Often, a plurality of such thermoelectric elements are connected to a thermoelectric generator, which can generate an electric current from a temperature difference in conjunction with a corresponding heat current. If an electrical voltage is applied to these thermoelectric modules so that an electric current flows through these, the elements can be used as so-called Peltier elements for cooling or heating.

Alternatively, such thermoelectric devices may be used in combustion engines, in particular, in motor vehicles, for waste heat recovery, for example to convert waste heat contained in the exhaust gas into electrical energy. In addition, other components of the motor vehicle, such as battery systems, can be temperature-controlled, i.e. cooled or heated.

Conventional thermoelectric elements are typically produced with a pin-like geometry rather than with so-called “pins”, at the front side of which, the electrical contacting is provided.

Thereby, it has often been proven to be problematic that thermoelectric elements designed in such a way are prone to mechanical damage. In addition, in the case of such an embodiment of thermoelectric elements, there is relatively little leeway in the design of a thermoelectric module with a multitude of such thermoelectric elements, which are electrically connected to each other.

### SUMMARY

The present invention therefore deals with the problem of indicating an improved or at least an alternative embodiment for a thermoelectric device of the aforementioned type, which is particularly characterized by improved mechanical characteristics.

This problem is solved by means of the object of the independent patent claims. Favourable embodiments are the object of the dependent patent claims.

The basic idea of the invention is to arrange a thermoelectric element made of a thermoelectrically active material in a plastic housing for later use in a thermoelectric module or in a thermoelectric assembly with a plurality of such elements respectively and by means of two electrical connection elements, which are connected to the thermoelectric element in a substance-to-substance manner, to establish an electrical connection to the exterior environment of the housing.

In the case of a device designed in this manner consisting of a thermoelectric element and a housing, the thermoelectric element arranged within the housing's interior space is effectively protected against outer mechanical influences. In particular, protection against externally acting mechanical forces and impacts as well as protection against externally imposed tensions result, which could affect the substance-to-substance connection—typically a soldering point—and the thermoelectric element. The thermoelectric element is also protected against excessive mechanical stresses, in particular, being protected against thermomechanical tensions. However, due to the electrical connection elements led towards the outside, a simple electrical contacting of the thermoelectric element is possible, thereby resulting in a variety of flexible possible uses. In particular, it is possible to install the thermoelectric device according to the invention with the thermoelectric element and with the element-protecting housing in a simple manner in large quantities onto printed circuit boards or other suitable substrates, in particular, with the aid of the so-called “Surface Mount Technology (SMT)”.

A thermoelectric device according to the invention comprises an open housing made of a plastic, which partially limits a housing's interior space. The housing comprises a first side wall and a second side wall lying opposite to the first side wall. A thermoelectric element made of a thermoelectrically active material is arranged in the housing's interior space. Furthermore, a first electrical connection element is arranged on an inner side of the first side wall and a second electrical connection element is arranged on the inner side of the second side wall, each for electrically connecting the thermoelectric element to an external electrical power supply with an electrical energy store or with an electrical consumer device. Furthermore, the electrical connection elements transport the heat to the thermoelectric element or away from this—depending where the cold and hot sides of the thermoelectric device are arranged—and must therefore have a line cross-sectional area that is considerably higher than what is required for the transport of the electrical load carrier. According to the invention, the first electrical connection element is connected to a first front side of the thermoelectric element facing the first side wall. In an analogous manner, the second electrical connection element is connected to a second front side of the thermoelectric element facing the second side wall in a substance-to-substance manner.

In accordance with a preferred embodiment, a first and second intermediate region is present between the thermoelectric element and the first as well as the second electrical connection element. In the first intermediate region, a first substance-to-substance connection of the thermoelectric element to the first electrical connection element is formed. In the second intermediate region, a second substance-to-substance connection of the thermoelectric element to the second electrical connection element is formed. The said intermediate regions can thereby be used to form the said substance-to-substance connection during the course of assembling the thermoelectric device.

Expediently, the substance-to-substance connection can be a solder connection. In this case, in the aforementioned intermediate regions, a suitable soldering paste or another suitable soft solder can be introduced. If the entire thermoelectric device together with the housing and thermoelectric element is soldered onto a circuit board by means of surface mount technology, in this way, the thermoelectric element can be soldered onto the two electrical connection elements.

Being particularly expedient, the first and/or second intermediate region is/are preferably formed in a gap-like manner with a gap width between 0.05 mm and 0.2 mm, preferably between 0.05 mm and 0.1 mm. Such a gap width has proven to be particularly favourable for introducing the said soft solder.

In the case of another favourable further embodiment, the assembly of the thermoelectric device is facilitated, in accordance with which, a top housing opening is formed on a top side of the housing, through which the thermoelectric element can be inserted into the housing's interior space.

In the case of another preferred embodiment, an upper end section of the first electrical connection element facing the top side of the housing is arranged at an angle, preferably at a sharp angle, to a main section of the first connection element, which abuts the inner side of the first side wall. In addition or as an alternative, in the case of this embodiment, a upper end section of the second electrical connection element facing the top side of the housing is arranged at an angle, preferably at a sharp angle, to a main section of the second connection element, which abuts the inner side of the second side wall. In this way, an intermediate region with a diameter increasing towards the top side of the housing can be formed between the thermoelectric element and in the upper end section of the respective electrical connection element. Such an intermediate region tapering away from the top side significantly facilitates the introduction of the soft solder or the solders paste into the intermediate region between the thermoelectric element and the electrical connection element.

In accordance with a favourable further embodiment, an upper end section of the first side wall comprises a first chamfering so that the upper end section of the first or second electrical connection element abuts the upper end section of the first or second side wall in a positive-locking manner. In addition or as an alternative, in the case of this further embodiment, an upper end section of the second side wall comprises a second chamfering so that the upper end section of the second electrical connection element abuts the upper end section of the second side wall in a positive-locking manner. In this way, the upper end section arranged at an angle to the main section can be fixed to the housing in a mechanically stable manner.

Being particularly preferred, the two electrical connection elements are led out through the underside of the housing towards the outside of the housing's interior space. This makes it possible to solder the two electrical connection elements to a suitable substrate in a simple way, for example, in the form of a circuit board.

In accordance with another preferred embodiment, the underside of the housing lying opposite to the top side is open. As a result, the contact surface between the thermoelectric element and the housing can be kept small. In this way, undesired thermomechanical tensions between the material of the thermoelectric element and the material of the housing can be minimized. In addition, parasitic heat flows are reduced by thermal bypasses between the hot and cold sides.

In accordance with a preferred embodiment, the first electrical connection element is led through a first breakthrough provided on the underside of the housing. Furthermore, in the case of this embodiment, the second electrical connection element is led through a second breakthrough provided on the underside of the housing.

In accordance with a favourable further embodiment, a lower end section of the first electrical connection elements protruding out of the first breakthrough towards the outside is flipped away from the second connection element. In addition or as an alternative, in the case of this further embodiment, a lower end section of the second electrical connection element protruding out of the second breakthrough towards the outside is flipped away from the first connection element. In this way, the design height of the housing can be kept low. Simultaneously, electrical connection elements are fixed to the outside of the housing in a mechanically stable manner.

Being particularly preferred, the lower end section of the first and/or the second electrical connection element abuts the underside of the housing. In this way, the respective electrical connection element is fixed to the underside of the housing. Thereby, a later soldering of the respective electrical connection element to a suitable substrate, for example, a circuit board, is facilitated by means of surface mount technology in particular.

In accordance with another favourable further embodiment, a third breakthrough is provided on the underside of the housing between the first and the second breakthrough, which is separated from the first and second breakthrough by means of a support structure. The thermoelectric element arranged in the housing's interior space abuts the support structure separating the breakthroughs in this further embodiment. A contact surface between the underside of the thermoelectric element arranged in the housing's interior space and the housing is minimized in this way. Mechanical tensions, in particular, thermomechanical tensions between the thermoelectric element and the housing are minimized. Similarly, the thermal contact between the thermoelectric element and the housing can be kept low.

Preferably, the support structure comprises two separation elements arranged at a distance from one another. Thereby, the first separation element separates the third breakthrough from the first breakthrough and the second separation element separates the third breakthrough from the second breakthrough. With the aid of the aforementioned breakthroughs, the mechanical contact surface of the housing along with the thermoelectric element arranged in the housing's interior space can be kept small. In this way, thermomechanical tensions between the housing and the thermoelectric element are minimized.

Expediently, the two separation elements can each be designed as struts. In this way, the contact surface between the housing and the thermoelectric element can be kept particularly small.

Expediently, both separation elements and struts can be formed on the housing in an integrated manner. This simplifies the production process of the housing, thereby being associated with cost advantages for the entire thermoelectric device.

It is particularly expedient if a lower housing opening provided on the underside is divided into the first, second and third breakthrough by means of the two separation elements or struts and, preferably, it is only limited or bordered by the side walls of the housing. This variant requires a particularly low level of material for the housing, thereby being associated with cost advantages in the production of the entire thermoelectric device.

Being particularly preferred, both electrical connection elements are respectively designed as conducting paths, preferably being made of copper or aluminium. Thereby, the connection elements can be soldered onto a circuit board by means of surface mount technology.

The invention furthermore relates to a thermoelectric assembly with a substrate, on which a plurality of thermoelectric devices presented earlier are arranged. The previously explained advantages of the thermoelectric device according to the invention therefore are also carried over to assembly according to the invention. According to the invention, at least two, preferably all thermoelectric devices of the assembly are electrically connected to one another by means of their electrical connection elements.

In accordance with a preferred embodiment, the thermoelectric elements of the assembly are electrically connected in series.

In accordance with another preferred embodiment, the substrate is a circuit board. In the case of this embodiment, the electrical connection of the thermoelectric elements is implemented via conductor paths arranged on the circuit board.

Other important features and advantages of the invention result from the subclaims, the drawings and the related figure description based on the drawings.

It is to be understood that the features explained in the aforementioned and following cannot only be used in the respectively indicated combination, but also in other combinations or alone, without departing from the scope of the present invention.

### BRIEF DESCRIPTION OF THE DRAWINGS

Preferred exemplary embodiments of the invention are represented in the drawings and will be described in more detail in the following description, wherein the same reference numbers will refer to the same or similar or functionally identical components.

On a schematic level respectively, the figures show:

FIG. 1, 2 an example of a thermoelectric device according to the invention in different perspective views,

FIG. 3a top view of a top side of the thermoelectric device in FIGS. 1 and 2,

FIG. 4the thermoelectric element in FIGS. 1 to 3 in a longitudinal section along the section line IV-IV in FIG. 3,

FIG. 5 a top view of an underside of the thermoelectric device in FIGS. 1 to 4.

### DETAILED DESCRIPTION

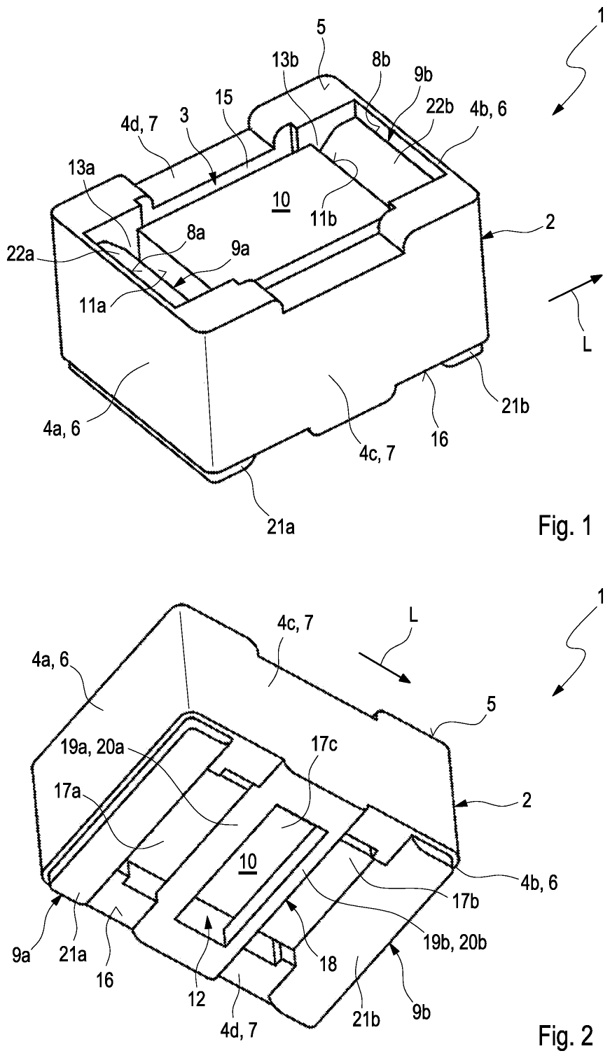

FIGS. 1 and 2 show an example of a thermoelectric device 1 according to the invention in different perspective views. The thermoelectric device 1 comprises an open housing 2 made of an electrically insulating material, such as a plastic for example. The housing 2 limits a housing's interior space 3. The housing 2 comprises a first side wall 4a as well as a second side wall 4a lying opposite to the first side wall 4a. The two side walls 4a, 4b are, in turn, connected to one another by means of a third and a fourth side wall 4c, 4d, which are also located opposite to one another. In a top view of a top side 5 of the housing 2, the first and the second side wall 4a, 4b form narrow sides 6 and the third and fourth side wall 4c, 4d form longitudinal sides 7 of the housing 2, which have the geometry of a rectangle in the top view of the top side 5 of the housing 2. In a special case (not shown), the geometry of a square is particularly conceivable. However, other housing geometries are also possible, for example geometries where at least one intermediate angle between two adjacent side walls 4a-4d deviate by 90°.

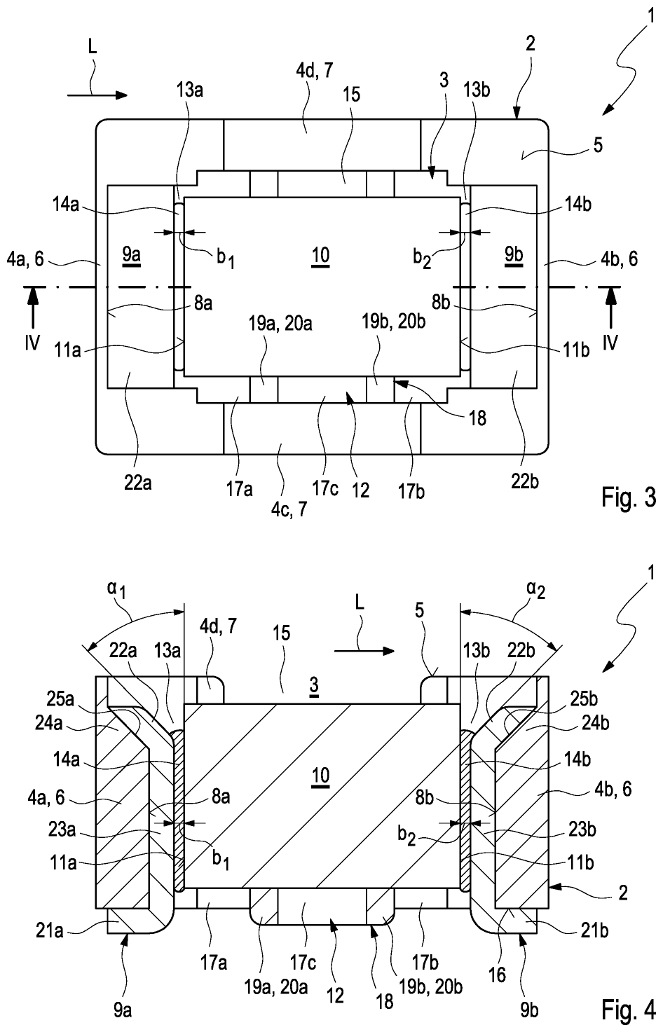

In accordance with FIGS. 1 and 2, a thermoelectric element 10 made of thermoelectrically active material is arranged in the housing's interior space 3. In particular, bismuth telluride comes under consideration as a thermoelectrically active material. In the example scenario, the thermoelectric element 10 has a cube or cuboid geometry. On the top side 5 of the housing 2, this comprises an upper housing opening 15, through which the thermoelectric element 10 can be inserted into the housing's interior space 3. This is particularly evident in the illustration of FIG. 3, which shows a top view of a top side of the thermoelectric device in FIGS. 1 and 2.

FIG. 4 shows the thermoelectric device 1 in FIGS. 1 to 3 in a longitudinal section along the section line IV-IV in FIG. 3. As can be recognized in FIG. 4, a first electrical connection element 9a is arranged on an inner side 8a of the first side wall 4a, and a second electrical connection element 9b is arranged on an inner side 8b of the second side wall 4b. The two electrical connection elements 9a, 9b serve to electrically connect the thermoelectric element 10 to an external electrical power supply. For this purpose, the first electrical connection element 9a is connected to a first front side 11a of the thermoelectric element 10 facing the first side wall 4a. Accordingly, the second electrical connection element 9b is connected to a second front side 11b of the thermoelectric element facing the second side wall 4b, which lies opposite to the first front side 11a. Both electrical connection elements 9a, 9b can respectively be designed as conducting paths, preferably being made of copper or aluminium.

As can be recognized in FIG. 3, a first intermediate region 13a is formed between the thermoelectric element 10 and the first electrical connection element 9a. In this first intermediate region 13a of the assembled device 1, a first substance-to-substance connection 14a of the thermoelectric element 10 to the first electrical connection element 9a is present. In an analogous manner, a second intermediate region 13b is formed between the thermoelectric element 10 and the second electrical connection element 9b. In this second intermediate region 13b, a second substance-to-substance connection 14b of the thermoelectric element 10 to the second electrical connection element 9b is present. Both substance-to-substance connections 14a, 14b are preferably solder connections.

During the course of assembling the device 1, the thermoelectric element 10 is inserted into the housing's interior space 3 in such a way that the two intermediate regions 13a, 13b result. Both intermediate regions 13a, 13b can then be filled with a soldering paste or another suitable soft solder. For this purpose, in accordance with FIG. 3, the two intermediate regions 13a, 13b are preferably each formed in a gap-like manner with a gap width b1 and b2 between 0.05 mm and 0.2 mm, preferably between 0.05 mm and 0.1 mm. The gap widths b1, b2 are preferably measured along a longitudinal direction L, which extends parallel to the two longitudinal sides 7. A side length s of the two longitudinal sides 7 typically ranges between 0.5 mm and 5 mm.

As is clearly proven in FIG. 2 in particular, an underside 16 of the housing 2 located opposite to the top side 5 is also open. In this way, the two electrical connection elements 9a, 9b can be led out through the underside 16 of the housing 2 towards the outside of the housing 2 and the housing's interior space 3.

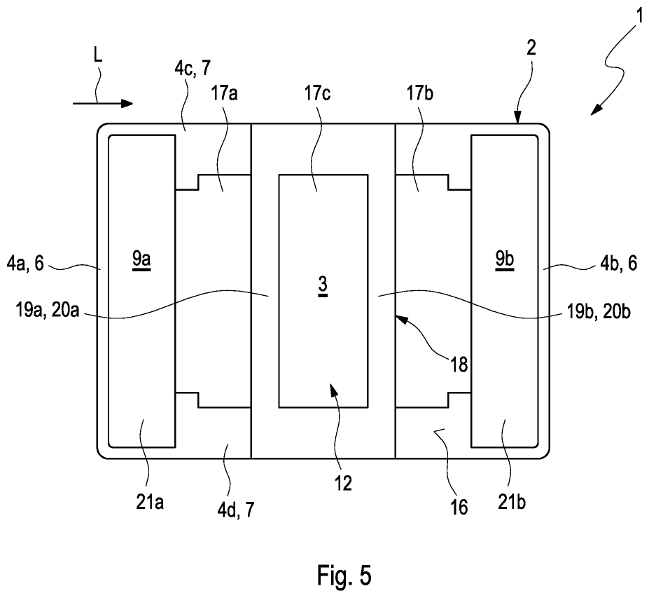

FIG. 5 shows a top view of the underside 16 of the housing 2 without a thermoelectric element 10 arranged in the housing's interior space 3. In accordance with FIGS. 2 and 5, the first electrical connection element 9a is led through a first breakthrough 17a provided on the underside 16 of the housing. Accordingly, the second electrical connection element 9b is led through a second breakthrough 17b provided on the underside 16 of the housing 2. In the example scenario, a third breakthrough 17c is provided on the underside 16 of the housing 2 between the first and the second breakthrough 17a, 17b. The third breakthrough 17c is separated from the first and from the second breakthrough 17a, 17b by means of a support structure 18. The thermoelectric element 10 arranged in the housing's interior space 3 (cf. FIGS. 2 and 4) abuts this support structure 18 and is supported on this. For this purpose, the support structure 18 comprises two separation elements 19a, 19b arranged at a distance to one another, which can each be formed like struts 20a, 20b. Thereby, the first separation element 19a separates the third breakthrough 17c from the first breakthrough 17a and the second separation element 19b separates the third breakthrough 17c from the second breakthrough 17b. Expediently, both separation elements 19a, 19b and the two struts 20a, 20b are formed on the housing (2) in an integrated manner.

It is directly evident from FIGS. 2 and 4, that a lower end section 21a of the first electrical connection element 9a protruding out of the first breakthrough 17a towards the outside is flipped away from the second electrical connection element 9b. Similarly, a lower end section (21b) of the second electrical connection element (9b) protruding out of the second breakthrough (17b) towards the outside is flipped away from the first electrical connection element (9a). Expediently, the two lower end sections 21a, 21b of the first and the second electrical connection element 9a, 9b abut the underside 16 of the housing 2. The three breakthroughs 17a, 17b, 17c thereby form a lower housing opening 12 on the underside 16 of the housing 2. Thereby, the lower housing opening 12 is divided into the first, second and third breakthrough 17a, 17b, 17c by means of the two separation elements 19a, 19b or struts 20a, 20b. Preferably, the lower housing opening 12 is only bordered by the side walls 4a, 4b, 4c, 4d of the housing 2, thereby being limited. The main section 23a, 23b of the first and second electrical connection element 9a, 9b thereby abuts the respective inner side 8a, 8b of the first or second side wall 4a, 4b.

If you look at the illustration of FIG. 4, you furthermore recognize that an upper end section 22a, 22b of the first or second electrical connection element 9a, 9b facing the top side 5 of the housing 2 is arranged at an angle, preferably at a sharp angle α1 or α2, to a main section 23a, 23b of the respective connection element 9a, 9b. The two electrical connection elements 9a, 9b respectively pass from the lower end section 21a or 21b into the main section 23a or 23b and pass from this into the upper end section 22a or 22b. The upper and lower end section 22a, 21a, 22b, 21b and the main section 23a, 23b arranged in between of the respective connection element 9a, 9b are preferably integrally formed onto each other.

As is shown in FIG. 4 in particular, a first upper end section 24a first of the first side wall 4a can comprise a first chamfering 25a so that the upper end section 22a of the first electrical connection element 9a abuts the upper end section 24a of the first side wall 4a in a positive-locking manner. Accordingly, a second upper end section 24b of the second side wall 4b can comprise a second chamfering 25b so that the upper end section 22b of the second electrical connection element 9b abuts the upper end section 24b of the second side wall 4b in a positive-locking manner.

1. A thermoelectric device comprising:
a housing made of a plastic, which partially limits an interior space and which includes a first side wall and a second side wall lying opposite to the first side wall; and
a thermoelectric element made of a thermoelectrically active material arranged in the interior space;
wherein a first electrical connection element is arranged on an inner side of the first side wall, and a second electrical connection element is arranged on an inner side of the second side wall; and
wherein the first electrical connection element is connected in a substance-to-substance manner to a first front side of the thermoelectric element facing the first side wall, and the second electrical connection element is connected to a second front side of the thermoelectric element facing the second side wall.

2. The thermoelectric device according to claim 1, wherein, between the thermoelectric element and the first electrical connection element and the second electrical connection element, a first or a second intermediate region is present and in which a first or a second substance-to-substance connection of the thermoelectric element is formed with the first or the second electrical connection element.

3. The thermoelectric device according to claim 2, wherein the first or the second substance-to-substance connection is a solder connection.

4. The thermoelectric device according to claim 2, wherein at least one of the first and the second intermediate region is formed in a gap-like manner with a gap width between 0.05 mm and 0.2 mm.

5. The thermoelectric device according to claim 1, wherein, on a top side of the housing, a top housing opening is formed, through which the thermoelectric element being inserted into the housing's interior space through the top housing opening.

6. The thermoelectric device according to claim 5, wherein an upper end section of at least one of the first and the second electrical connection element facing the top side of the housing is at an angle to a main section to the respective connection element, said main section abutting the respective inner side of the associated side wall of the housing.

7. The thermoelectric device according to claim 5, wherein an upper end section of at least one of the first and the second side wall includes a first or a second chamfering so that an upper end section of the first or the second electrical connection element abuts the upper end section in a positive-locking manner.

8. The thermoelectric device according to claim 1, wherein:
the first and the second electrical connection elements are led out through the underside of the housing towards the outside of the housing's interior space (3).

9. The thermoelectric device according to claim 8, wherein the underside of the housing is open.

10. The thermoelectric device according to claim 8, wherein the first electrical connection element is led through a first breakthrough provided on the underside of the housing, and the second electrical connection element is led through a second breakthrough provided on the underside of the housing.

11. The thermoelectric device according to claim 1, wherein at least one of:
a lower end section of the first electrical connection element protruding out of the first breakthrough towards the outside is flipped away from the second electrical connection element; and/or that
a lower end section of the second electrical connection element protruding out of the second breakthrough towards the outside is flipped away from the first electrical connection element.

12. The thermoelectric device according to claim 11, wherein the lower end section of at least one of the first and the second electrical connection element abuts the underside of the housing.

13. The thermoelectric device according to claim 8, wherein a third breakthrough is provided on the underside of the housing between the first and the second breakthrough, the third breakthrough being separated from one of the first or the second breakthrough via a support structure, which the thermoelectric element arranged within the interior space abuts.

14. The thermoelectric device according to claim 13, wherein:
the support structure includes two separation elements arranged at a distance away from one another; and
one of the two separation elements separates the third breakthrough from the first breakthrough, and the other of the two separation elements separates the third breakthrough from the second breakthrough.

15. The thermoelectric device according to claim 14, wherein the two separation elements are respectively designed as struts.

16. The thermoelectric device according to claim 14, wherein the two separation elements are formed on the housing in an integrated manner.

17. The thermoelectric device according to claim 14, wherein a lower housing opening provided on the underside is divided into the first, second and third breakthroughs via the two separation elements.

18. The thermoelectric device according to claim 1, wherein the first and the second electrical connection elements are at least one of (i) respectively designed as conducting paths, and (ii) made of copper or aluminium.

19. The thermoelectric device according to claim 1, wherein the thermoelectric element has a cube or cuboid geometry.

20. A thermoelectric assembly, comprising:
a substrate;
a plurality of thermoelectric devices arranged on the substrate, each thermoelectric device having:
a housing made of a plastic, which partially limits an interior space and which includes a first side wall and a second side wall lying opposite to the first side wall; and
a thermoelectric element made of a thermoelectrically active material arranged in the interior space;
wherein a first electrical connection element is arranged on an inner side of the first side wall, and a second electrical connection element is arranged on an inner side of the second side wall:
wherein the first electrical connection element is connected in a substance-to-substance manner to a first front side of the thermoelectric element facing the first side wall, and the second electrical connection element is connected to a second front side of the thermoelectric element facing the second side wall;
wherein the thermoelectric devices are electrically connected to each other via the first and the second electrical connection elements.

21. The thermoelectric assembly according to claim 20, wherein the thermoelectric elements are electrically connected in series.

22. The thermoelectric assembly according to claim 20, wherein:
the substrate is a circuit board; and
the electrical connection of the thermoelectric elements is implemented via conductor paths arranged on the circuit board.
